(19) United States
(12) Patent Application Publication
(10) Pub. No.: US 2025/0098162 A1
(43) Pub. Date: Mar. 20, 2025

(54) MEMORY DEVICE AND METHOD OF FORMING THE SAME

(71) Applicant: MACRONIX International Co., Ltd., Hsinchu (TW)

(72) Inventors: Ting-Feng Liao, Hsin-chu (TW); Mao-Yuan Weng, Hualien County (TW); Kuang-Wen Liu, Hsinchu County (TW)

(73) Assignee: MACRONIX International Co., Ltd., Hsinchu (TW)

(21) Appl. No.: 18/466,820

(22) Filed: Sep. 14, 2023

(51) Int. Cl. H10B 43/27; H10B 41/10; H10B 41/27; H10B 43/10

(52) U.S. Cl. CPC H10B 43/27; H10B 41/10; H10B 41/27; H10B 43/10

(57) ABSTRACT

A memory device includes, from bottom to top, a substrate, a laminated layer and a stacked structure. Vertical channel pillars penetrate through the stacked structure and the laminated layer. First isolation structures are disposed aside the vertical channel pillars and penetrate through a lower part of the stacked structure. Second isolation structures are disposed over the first isolation structures and penetrate through an upper part of the stacked structure. Common source lines are disposed aside the vertical channel pillars and penetrate through the stacked structure and part of the laminated layer. From a top view, the common source lines extend in a first direction. Each of the first and second isolation structures has, in the first direction, two wide end portions respectively adjacent to two common source lines. The memory device may be applied in the process of manufacturing a 3D NAND flash memory with high capacity and high performance.

### BACKGROUND

### Technical Field

The present disclosure is related to a semiconductor device and a method of forming the same, and particularly to a memory device and a method of forming the same.

### Description of Related Art

A non-volatile memory device (e.g., a flash memory) has the advantage that stored data does not disappear at power-off, so it becomes a widely used memory device for a personal computer or other electronic equipment.

Currently, the flash memory arrays commonly used in the industry include a NOR flash memory and a NAND flash memory. The NAND flash memory has multiple memory cells connected in series, so the NAND flash memory has better integration and area utilization than the NOR flash memory, and has been widely used in various electronic products. In addition, in order to further enhance the integration of memory devices, a 3-dimensional NAND flash memory has been developed. However, there are still many challenges associated with a 3-dimensional NAND flash memory.

### SUMMARY

The present disclosure provides a memory device and its forming method, so as to form a memory device with improved reliability.

The present disclosure provides a memory device, which includes, from bottom to top, a substrate, a laminated layer and a stacked structure. A plurality of vertical channel pillars penetrate through the stacked structure and laminated layer. A plurality of first isolation structures are disposed aside the vertical channel pillars and penetrate through a lower part of the stacked structure. A plurality of second isolation structures are respectively disposed over the multiple first isolation structures and penetrate through an upper part of the stacked structure. A plurality of common source lines are disposed aside the vertical channel pillars and penetrate through the stacked structure and a part of the laminated layer. From a top view, the common source lines extend in a first direction, and each of the first isolation structures and the second isolation structures has, in the first direction, two wide end portions respectively adjacent to two of the common source lines.

The present disclosure further provides a method of forming a memory device including the following steps. A laminated layer is formed on a substrate. A stacked structure is formed on the laminated layer, and the stacked structure includes a plurality of insulating layers and a plurality of conductive layers stacked alternately. A plurality of vertical channel pillars, a plurality of first isolation structures and a plurality of second isolation structures are formed in the stacked structure. The vertical channel pillars penetrate through the stacked structure and the laminated layer, the first isolation structures penetrate through a lower part of the stacked structure, and the second isolation structures are respectively disposed over the first isolation structures and penetrate through an upper part of the stacked structure. From a top view, each of the first isolation structures and the second isolation structures has two wide end portions in a first direction.

Based on the above, in the present disclosure, a source line isolation structure is formed with wide end portions at two sides thereof, so as to prevent a seam from forming in the source line isolation structure due to over-etching during the formation of the vertical trenches, and therefore prevent a tungsten layer from filling in the seam in the subsequent replacement process to cause the conventional short issue between the adjacent common source lines. Therefore, the reliability of the memory device formed by the present disclosure can be greatly improved.

### BRIEF DESCRIPTION OF THE DRAWINGS

FIG. 1A, FIG. 2A, FIG. 3A, FIG. 4A, FIG. 5A, FIG. 6A and FIG. 7A are schematic cross-sectional views of a method of forming a memory device according to an embodiment of the present disclosure.

FIG. 1B, FIG. 2B, FIG. 3B, FIG. 4B, FIG. 5B, FIG. 6B and FIG. 7B are simplified top views of a method of forming a memory device according to an embodiment of the present disclosure.

FIG. 8A, FIG. 9A and FIG. 10A are schematic cross-sectional views of a method of forming a memory device according to another embodiment of the present disclosure.

FIG. 8B, FIG. 9B and FIG. 10B are simplified top views of a method of forming a memory device according to another embodiment of the present disclosure.

### DESCRIPTION OF THE EMBODIMENTS

The embodiments are provided below and described in detail with the accompanying drawings, but the provided embodiments are not intended to limit the scopes contemplated by the present disclosure. In addition, the drawings are provided for illustration purposes only and are not drawn according to the original scale. In order to facilitate understanding, the same elements are described with the same reference numerals in the following description.

The terms “including”, “comprising”, “having” and so on used in the text are all open-ended terms, which mean “including but not limited to”.

Besides, the directional terms mentioned in the text, such as “on”, “below” and so on, are only used to refer to the direction of the drawings, and are not used to limit the present disclosure. Thus, it should be understood that “on” and “below” can be used interchangeably and that when an element such as a layer or film is disposed “on” another element, the element may be disposed directly on another element, or there may be an intervening element disposed therebetween. On the other hand, when an element is described to be “disposed directly on” another element, there is no intervening element disposed therebetween.

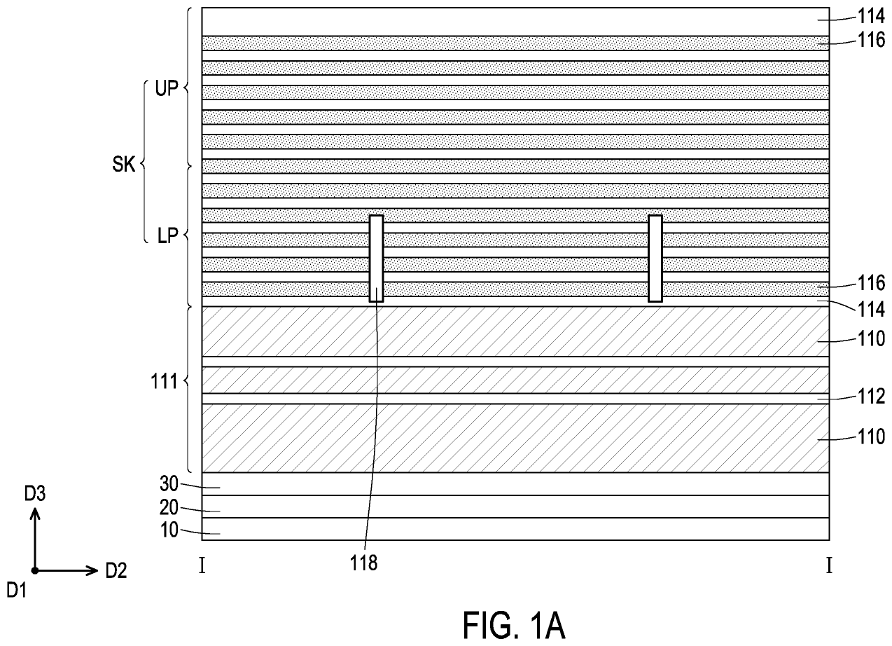

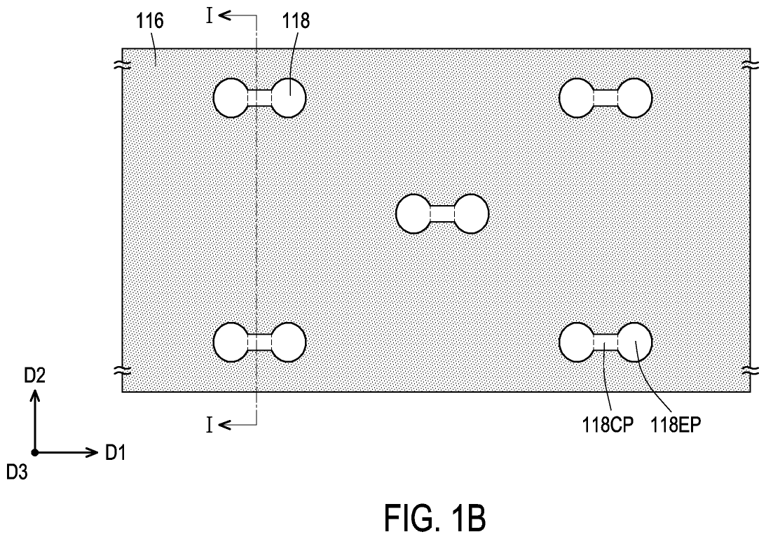

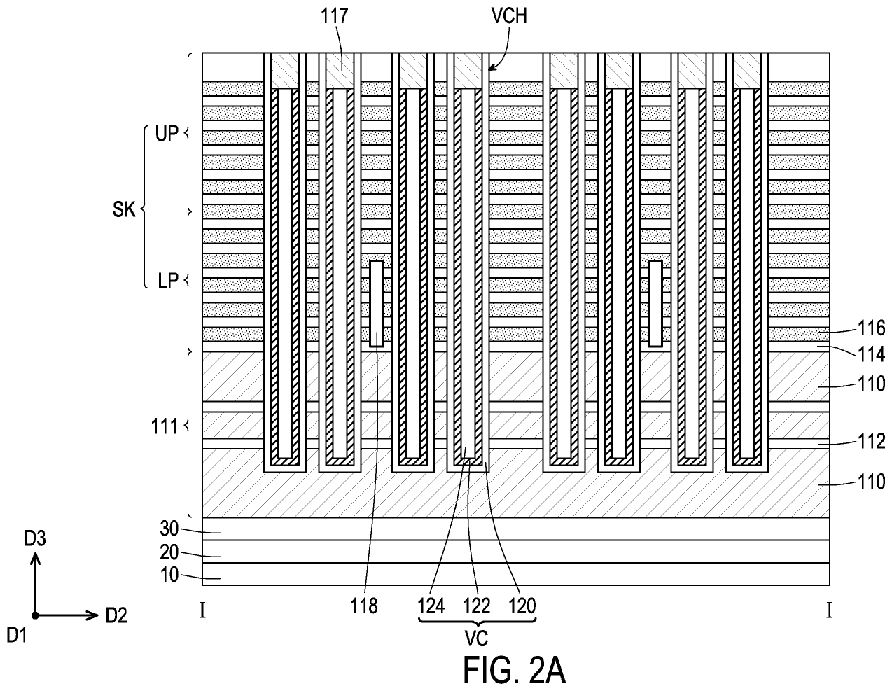

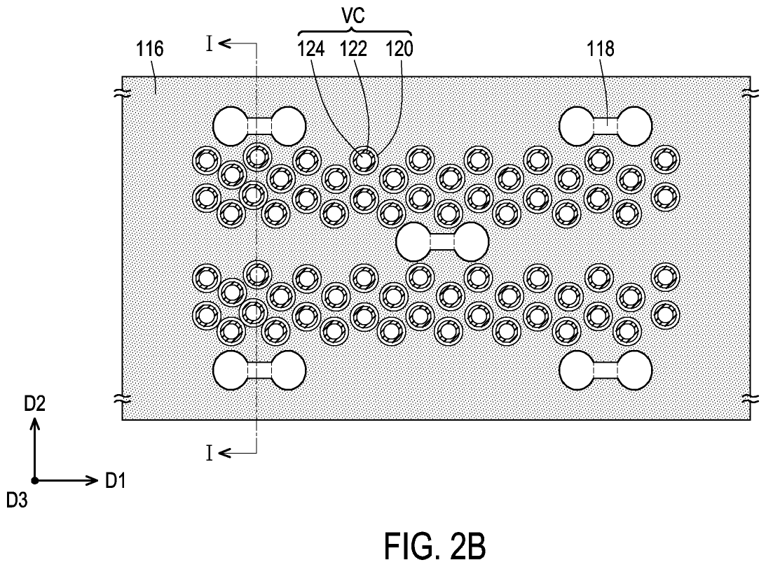

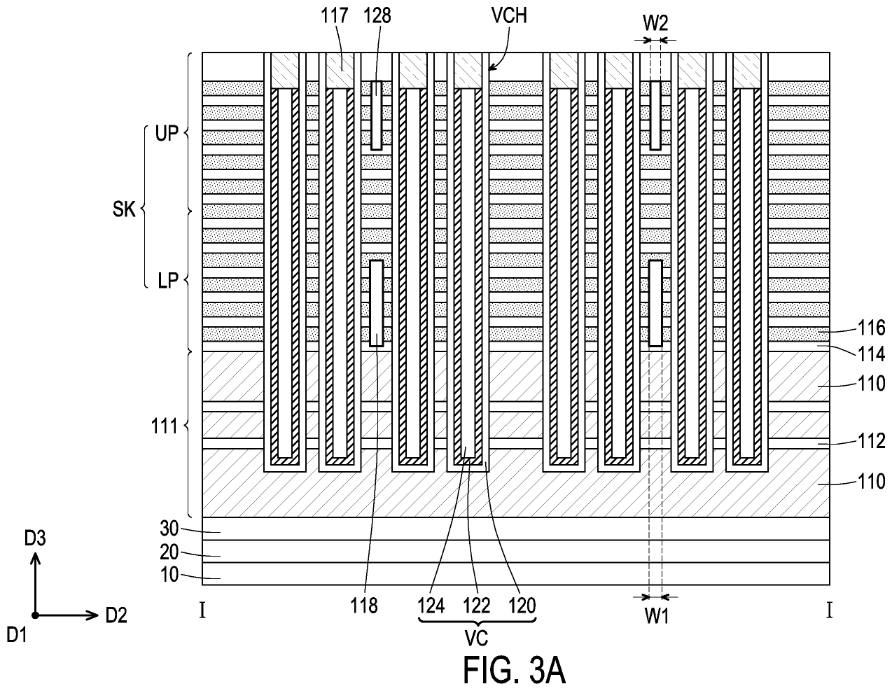

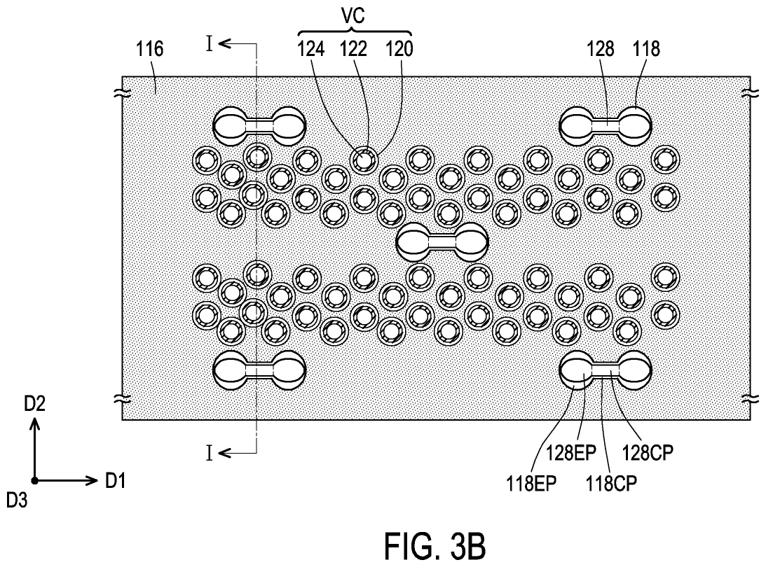

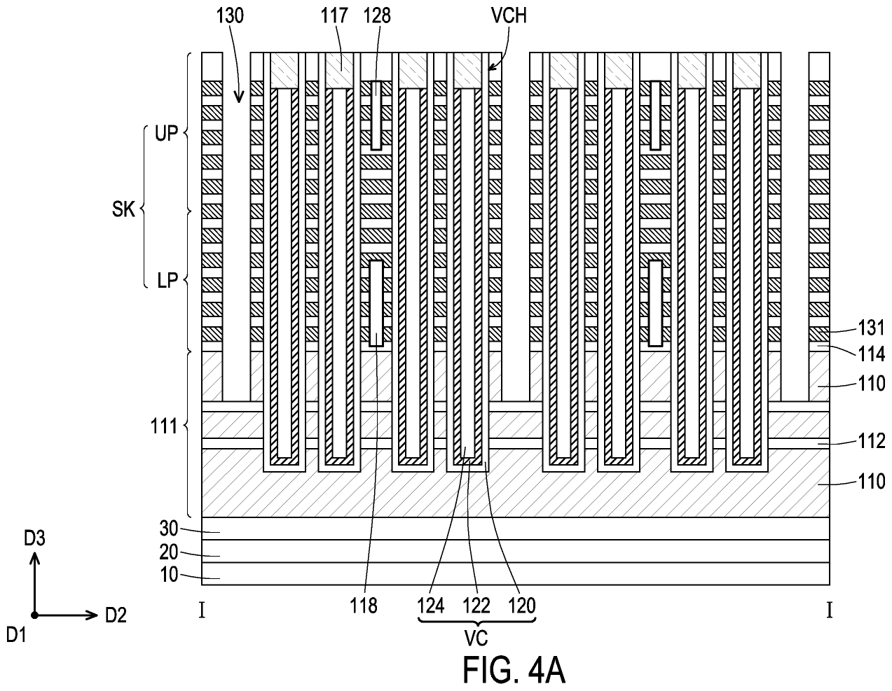

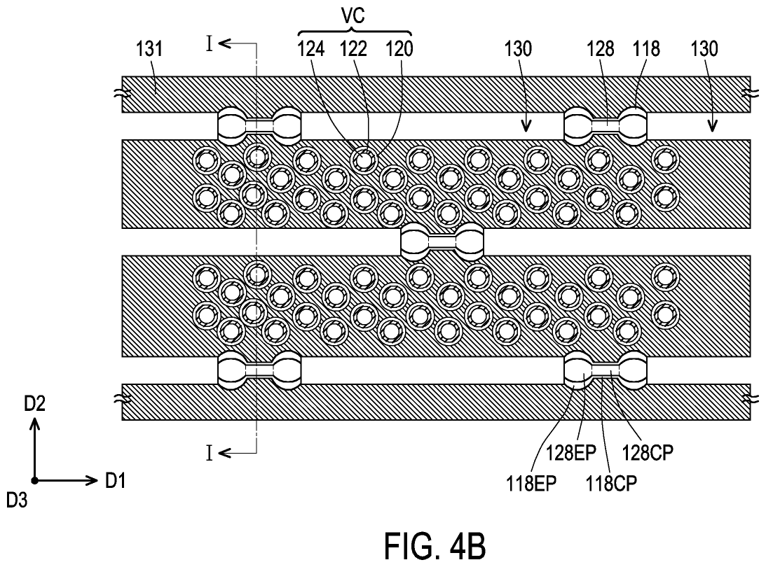

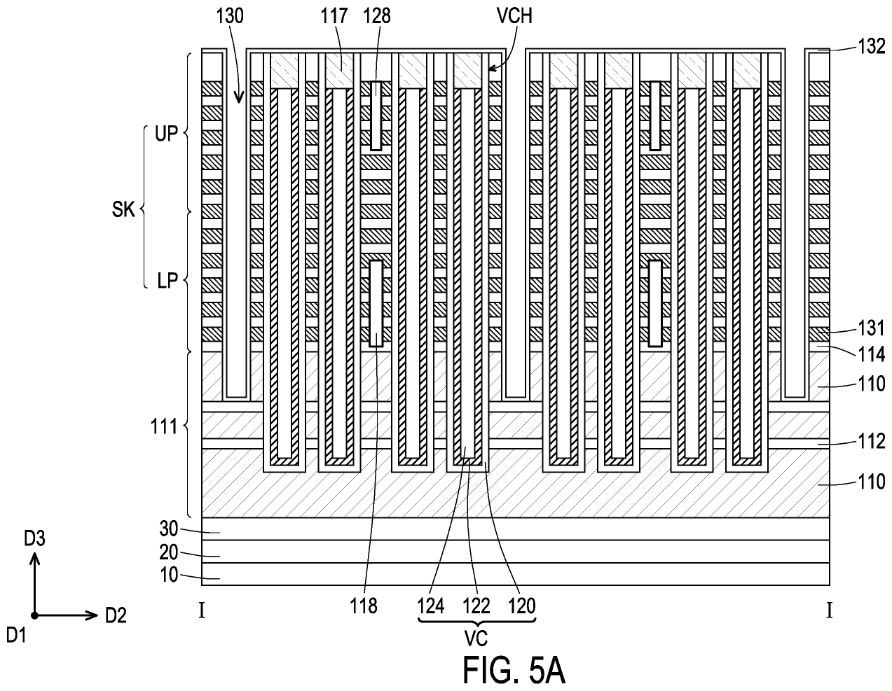

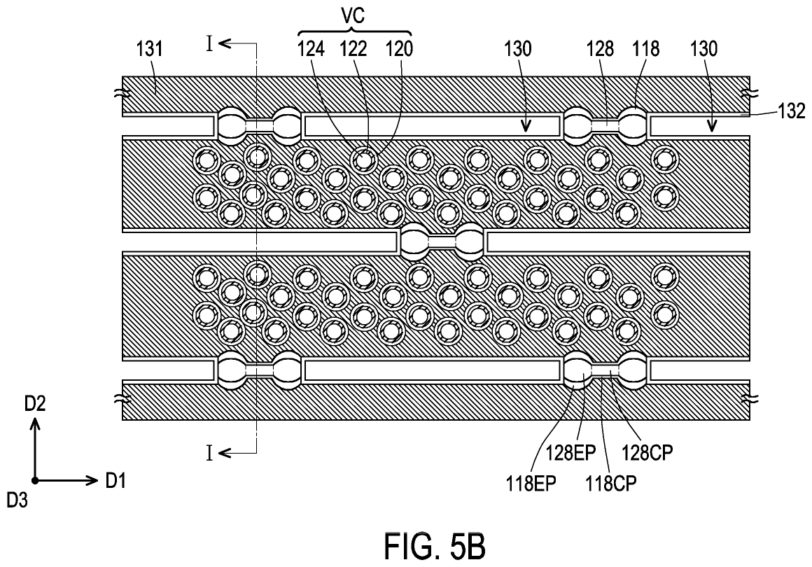

FIG. 1A, FIG. 2A, FIG. 3A, FIG. 4A, FIG. 5A, FIG. 6A and FIG. 7A are schematic cross-sectional views of a method of forming a memory device according to an embodiment of the present disclosure. FIG. 1B, FIG. 2B, FIG. 3B, FIG. 4B, FIG. 5B, FIG. 6B and FIG. 7B are simplified top views of a method of forming a memory device according to an embodiment of the present disclosure. In an embodiment, FIG. 1A, FIG. 2A, FIG. 3A, FIG. 4A, FIG. 5A, FIG. 6A and FIG. 7A are cross-sectional views taken along the lines I-I of FIG. 1B, FIG. 2B, FIG. 3B, FIG. 4B, FIG. 5B, FIG. 6B and FIG. 7B.

Referring to FIG. 1A, a substrate 10 is provided. In an embodiment, the substrate 10 includes a semiconductor substrate, such as a silicon-containing substrate. Thereafter, an device layer 20 is formed on the substrate 10. In an embodiment, the device layer 20 may include various well-known semiconductor devices. In an embodiment, the device layer 20 may include a metal oxide semiconductor (MOS) transistor formed at the surface of the substrate 10, and an interconnect structure electrically connected to the metal oxide semiconductor transistor, but the present disclosure is not limited thereto. The interconnect structure includes multiple dielectric layers and multiple interconnections in the plurality of dielectric layers. Thereafter, an insulating layer 30 is formed on the device layer 20. In an embodiment, the insulating layer 30 includes silicon oxide.

Afterwards, a laminated layer 111 is formed on the insulating layer 30. The laminated layer 111 includes multiple insulating layers 112 and multiple conductive layers 110 stacked alternately in a direction D3 (e.g., Z direction). In an embodiment, the insulating layers 112 include silicon oxide, and the conductive layers 110 include doped polysilicon. The numbers of the insulating layers 112 and the conductive layers 110 are not limited by the present disclosure.

Continue referring to FIG. 1A, a stacked structure SK is formed on the laminated layer 111. The stacked structure SK includes a lower part LP and an upper part UP. In an embodiment, each of the lower part LP and an upper part UP of the stacked structure SK includes multiple insulating layers 114 and multiple intermediate layers 116 alternately stacked in the direction D3 (e.g., Z direction). The numbers of the insulating layers 114 and the interlayers 116 are not limited by the present disclosure. In an embodiment, the insulating layers 114 include oxide layers, and the intermediate layers 116 includes nitride layers, but the present disclosure is not limited thereto. In other embodiments, the insulating layers 114 and the intermediate layers 116 may be other dielectric material layers, as long as there is an etching selectivity between the insulating layers 114 and the intermediate layers 116. In an embodiment, the intermediate layers 116 serve as sacrificial layers that are subjected to a subsequent replacement step. In another embodiment, the intermediate layers 116 are doped polysilicon layers without a replacement step.

In an embodiment, the lower part LP of the stacked structure SK is formed first. Thereafter, multiple first isolation structures 118 are formed in the lower part LP of the stacked structure SK. In an embodiment, the first isolation structures 118 may be referred to as “global select line cut (GLC) insulators”. The method of forming the first isolation structures 118 include: performing a patterning process (e.g., lithographic etching processes) to the lower part LP of the stacked structure SK to form multiple first holes; filling an isolation material (e.g., silicon oxide) in the first holes; and performing a chemical mechanical polishing (CMP) process to remove the excess isolation material outside of the first holes. The first isolation structures 118 penetrate through at least one insulating layer 114 and at least one intermediate layer 116 in the direction D3 (e.g., Z direction).

In an embodiment, the first isolation structures 118 have substantially vertical sidewalls, as shown in FIG. 1A. In another embodiment, the first isolation structures 118 may have inclined sidewalls. In an embodiment, each of the first isolation structures 118 may have a single-layer or multi-layer structure.

In this embodiment, the lower end of each first isolation structure 118 is covered by the insulating layer 114, and the upper end of the same is covered by the intermediate layer 116, as shown in FIG. 1A. However, the present disclosure is not limited thereto. In another embodiment, the lower end of each first isolation structure 118 is covered by the intermediate layers 116, and the upper end of the same is covered by the insulating layer 114. In other embodiments, both the lower end and the upper end of each first isolation structure 118 may be covered by the insulating layers 114, or covered by the intermediate layers 116.

From a top view, each first isolation structure 118 has a dumbbell-like shape, as shown in FIG. 1B. More specifically, from the top view, each first isolation structure 118 has, in a direction D1 (e.g., X direction), a narrow center portion 118CP and two wide end portions 118EP located at two sides of the narrow center portion 118CP. The narrow center portion 118CP has a bar-like shape, and each of the wide end portions 118EP has a circle-like shape. In an embodiment, the size of the wide end portions 118EP in a direction D2 (e.g., Y direction) is greater than the size of the narrow center portion 118CP in the direction D2, and the direction D2 is perpendicular to the direction D1. In an embodiment, from the top view, each narrow center portion 118CP has a substantially fixed width, and each wide end portion 118EP has a varied width.

Still referring to FIG. 1A, the upper part UP of the stacked structure SK is formed on the lower part LP of the stacked structure SK. In an embodiment, the uppermost layer of the stacked structure SK is the insulating layer 114. This uppermost insulating layer 114 may be referred to as a “capping layer”. The uppermost insulating layer 114 has a flat top surface. In an embodiment, the method of forming the uppermost insulating layer 114 includes forming a capping material layer on the stacked structure, and then performing a planarization process, such as a chemical mechanical polishing process.

Referring to FIG. 2A, multiple vertical channel pillars VC are formed in the laminated layer 111 and the stacked structure SK. The multiple vertical channel pillars VC are located aside the multiple first isolation structures 118, as shown in FIG. 2A and FIG. 2B. In an embodiment, a patterning process (e.g., lithographic etching processes) is performed to form multiple vertical channel holes VCH in the laminated layer 111 and the stacked structure SK. Thereafter, a charge storage structure 120 is conformally formed on the sidewall and the bottom of each vertical channel hole VCH. In an embodiment, the charge storage structure 120 may be an oxide/nitride/oxide (ONO) composite layer. Next, a channel layer 122 is formed on the charge storage structure 120 in each vertical channel hole VCH. In an embodiment, the channel layer 122 includes polysilicon. Afterwards, an insulating pillar 124 is formed on the channel layer 122 in each vertical channel hole VCH. In an embodiment, the insulating pillar 124 includes silicon oxide. In an embodiment, the charge storage structure 120, the channel layer 122 and the insulating pillar 124 form a vertical channel pillar VC. Afterwards, multiple conductive plugs 117 are formed on upper parts of the vertical channel holes VCH, and the conductive plugs 117 are in contact with the channel layers 122. In an embodiment, the conductive plugs 117 include doped polysilicon.

Referring to FIG. 3A, multiple second isolation structures 128 are formed in the upper part UP of the stacked structure SK. In an embodiment, the second isolation structures 128 may be referred to as “string select line cut (GSC) insulators”. The method of forming the second isolation structure 128 includes: performing a patterning process (e.g., lithographic etching processes) to the upper part UP of the stacked structure SK to form multiple second holes; filling an isolation material (e.g., silicon oxide) in the second holes; and performing a chemical mechanical polishing process to remove the excess isolation material outside of the second holes. The second isolation structures 128 penetrate through at least one insulating layer 114 and at least one intermediate layers 116 in the direction D3 (e.g., Z direction).

In an embodiment, the second isolation structures 128 have substantially vertical sidewalls, as shown in FIG. 3A. In another embodiment, the second isolation structures 128 may have inclined sidewalls. In an embodiment, each of the second isolation structures 128 may have a single-layer or multi-layer structure.

In this embodiment, the lower end of each second isolation structure 128 is covered by the insulating layer 114, and the upper end is flush with the uppermost intermediate layer 116, as shown in FIG. 3A. However, the present disclosure is not limited thereto. In another embodiment, the lower end of each second isolation structure 128 is covered by the intermediate layers 116, and the upper end is covered by the insulating layer 114. In other embodiments, both the lower end and the upper end of each second isolation structure 128 may be covered by the insulating layers 114, or covered by the intermediate layers 116.

From a top view, each second isolation structure 128 has a dumbbell-like shape, as shown in FIG. 3B. More specifically, from the top view, each second isolation structure 128 has a narrow center portion 128CP and two wide end portions 128EP located at two sides of the narrow center portion 128CP in the direction D1 (e.g., X direction). The narrow center portion 128CP has a bar-like shape, and each of the wide end portions 128EP has a circle-like shape. In an embodiment, the size of the wide end portions 128EP in the direction D2 (e.g., Y direction) is greater than the size of the narrow center portion 128CP in the direction D2, and the direction D2 is perpendicular to the direction D1. In an embodiment, from the top view, each narrow center portion 118CP has a substantially fixed width, and each wide end portion 118EP has a varied width.

In an embodiment, as shown in FIG. 3A, the first isolation structures 118 and the second isolation structures 128 are separated by at least one insulating layer 114 and at least one intermediate layer 116 in the direction D3 (e.g., Z direction). The first isolation structures 118 are substantially aligned with the second isolation structures 128 in the direction D3 (e.g., Z direction). In an embodiment, the first isolation structures 118 have a width W1, the second isolation structures 128 have a width W2, and width W2 is greater than width W1.

From the top view of FIG. 3B, the multiple second isolation structures 128 are respectively overlapped with the multiple first isolation structures 118, and the multiple second isolation structures 128 are respectively located within boundaries of the multiple first isolation structures 118. More specifically, the size of the narrow center portions 118CP of the first isolation structures 118 in the direction D2 (e.g., Y direction) is greater than the size of the narrow center portions 128CP of the second isolation structures 128 in the direction D2, and the size of the wide end portions 118EP of the first isolation structure 118 in the direction D2 (e.g., Y direction) is greater than the size of the wide end portions 128EP of the second isolation structures in the direction D2.

Referring to FIG. 4A, multiple vertical trenches 130 are formed in the stacked structure SK and a part of the laminated layer 111. The method of forming the vertical trenches 130 include performing photolithography and etching processes. In an embodiment, the vertical trenches 130 may be referred to as “slits”. In an embodiment, the vertical trenches 130 expose the insulating layer 112 of the laminated layer 111. In an embodiment, the vertical trenches 130 have substantially vertical sidewalls, as shown in FIG. 4A. In another embodiment, the vertical trenches 130 may have inclined sidewalls.

From the top view of FIG. 4B, the multiple vertical trenches 130 extend in the direction D1 (e.g., X direction). In an embodiment, each first isolation structure 118 has, in the direction D1, two wide end portions 118EP respectively adjacent to two vertical trenches 130. In an embodiment, each of the second isolation structures 128 has, in the direction D1, two wide end portions 128EP respectively adjacent to two vertical trenches 130.

In an embodiment, during the step of forming the vertical trenches 130, the wide end portions 118EP of the first isolation structures 118 and the wide end portions 128EP of the second isolation structures 128 are partially removed. From the top view of FIG. 4B, each vertical trench 130 exposes the wide end portion 118EP of the corresponding first isolation structure 118 and the wide end portion 128EP of the corresponding second isolation structure 128.

Next, the multiple intermediate layers 116 in the stacked structure SK are replaced with multiple conductive layers 131. More specifically, after the replacement process, the stacked structure SK includes multiple insulating layers 114 and multiple conductive layers 131 alternately stacked on the substrate 10. In an embodiment, when the intermediate layers 116 are doped polysilicon layers, the above replacement step may be optionally omitted.

In an embodiment, a selective etching process is performed, and the etchant contacts the intermediate layers 116 of the stacked structure SK exposed by the trench 130, and thus, the intermediate layers 116 of the stacked structure SK are etched and removed to form multiple horizontal openings. The selective etching process may include an isotropic etching process, such as a wet etching process. The etchant used in the wet etching process includes hot phosphoric acid. Thereafter, a conductive material layer is formed on the surface of the stacked structure SK, and filled in the trenches 130 and the horizontal openings. In an embodiment, the conductive material layer includes a barrier layer and a metal layer. In an embodiment, the barrier layer includes titanium (Ti), titanium nitride (TiN), tantalum (Ta), tantalum nitride (TaN) or a combination thereof. The metal layer includes tungsten (W). Thereafter, an etching back process is performed to remove the conductive material layer on the surface of the stacked structure SK and in the vertical trenches 130. The remaining conductive layer forms the conductive layers 131 in the horizontal openings.

Referring to FIG. 5A, an etch stop layer 132 is conformally formed on the top surface of the stacked structure SK and on the sidewalls and bottom surfaces of the vertical trenches 130. In an embodiment, the etch stop layer 132 includes an insulating layer, such as a nitride/oxide/nitride (NON) composite layer. From the top view of FIG. 5B, the etch stop layer 132 is in direct contact with the wide end portions 118EP of the first isolation structures 118 and the wide end portions 128EP of the second isolation structures 128.

Referring to FIG. 6A and FIG. 6B, the depth of the vertical trenches 130 are deepened, and a part of the etch stop layer 132 is removed, so that the remaining etch stop layer 132 remains on the sidewalls of the vertical trenches 130 in the form of spacers. Thereafter, the conductive layer 110 in the middle part of the laminated layer 111 and the underlying insulating layer 112 and the overlying insulating layer 112 are removed to form a lateral trench 134 in the laminated layer 111. The above removing step simultaneously removes a part of the charge storage layer 120 of each vertical channel pillar VC. In an embodiment, the lateral trench 134 exposes a portion of the channel layer 122 of each vertical channel pillar VC. More specifically, the channel layer 122 of each vertical channel pillar VC is discontinuous in the laminated layer 111. In an embodiment, the above removing step further thins the etch stop layer 132. For example, the original nitride/oxide/nitride (NON) etch stop layer 132 is thinned to a nitride layer.

Referring to FIG. 7A, a conductive layer 110′ (e.g., doped polysilicon layer) is back-filled in the lateral trench 134. In an embodiment, a doped polysilicon layer is formed on the surface of the stacked structure SK, and filled in the vertical trenches 130 and the lateral trench 134. Thereafter, an etching back process is performed to remove the doped polysilicon layer on the surface of the stacked structure SK and in the vertical trenches 130. The conductive layer 110′ in the lateral trench 134, the underlying conductive layer 110 and the overlying conductive layer 110 form a common source line or a ground line.

Continue referring to FIG. 7A, multiple common source lines 136 are formed in the multiple vertical trenches 130. The common source lines 136 are formed in the form of conductive walls. The multiple common source lines 136 extend in the direction D1 (e.g., X direction). In an embodiment, a conductive material (e.g., tungsten) is formed on the surface of the stacked structure SK and filled in the vertical trenches 130, and then a planarization process is performed to remove the conductive material outside of the vertical trenches 130. In an embodiment, each common source line 136 is electrically insulated from the adjacent conductive layers 131 by the etch stop layer 132. In another embodiment, the etch stop layer 132 is removed, an isolation pillar is formed in each vertical trench 130, and then one common source line 136 is formed through the isolation pillar. Thereafter, a bit line (BL) may be formed on the stacked structure SK, and the bit line is electrically connected to the underlying conductive plugs 117 of the vertical channel pillars VC through multiple conductive contacts. The memory device 100 of the present disclosure is thus completed.

In the memory device 100 of the disclosure, the stacked structure SK may include a lower section, a middle section and an upper section. The conductive layers 131 in the lower section of stacked structure SK serve as multiple global select lines (GSL). The conductive layers 131 in the middle section of the stacked structure SK serve as word lines (WL). The conductive layers 131 in the upper section of stacked structure SK serve as string select lines (SSL). Multiple global select line cut (GLC) insulators (e.g., first isolation structures 118) are configured in the global select lines GSL, and string select line cut (string select line cut, GSC) insulators (e.g., second isolation structures 128) are configured in the string select lines SSL. By such configuration, the operations of different blocks BK1 and BK2 (as shown in FIG. 7B) are not interfered with each other, so as to effectively improve the performance of the memory device.

The seams generated due to over-etching during the formation of the vertical trenches “open” the conventional single-size GLC/GSC insulators, a tungsten layer of the subsequent replacement process would be filled into the seams, so the conventional short circuit issue between adjacent common source lines occurs. In the present disclosure, the above short current issue is not observed because the first isolation structures 118 and/or the second isolation structures 128 are designed to have wide end portions.

In the above embodiments, the first isolation structures 118 and/or the second isolation structures 128 are void-free isolation structures. However, the present disclosure is not limited thereto. In another embodiment, under the process tolerance/variance, the first isolation structure 118 and/or the second isolation structure 128 may have enclosed voids, and such enclosed voids would not cause the conventional short circuit problems.

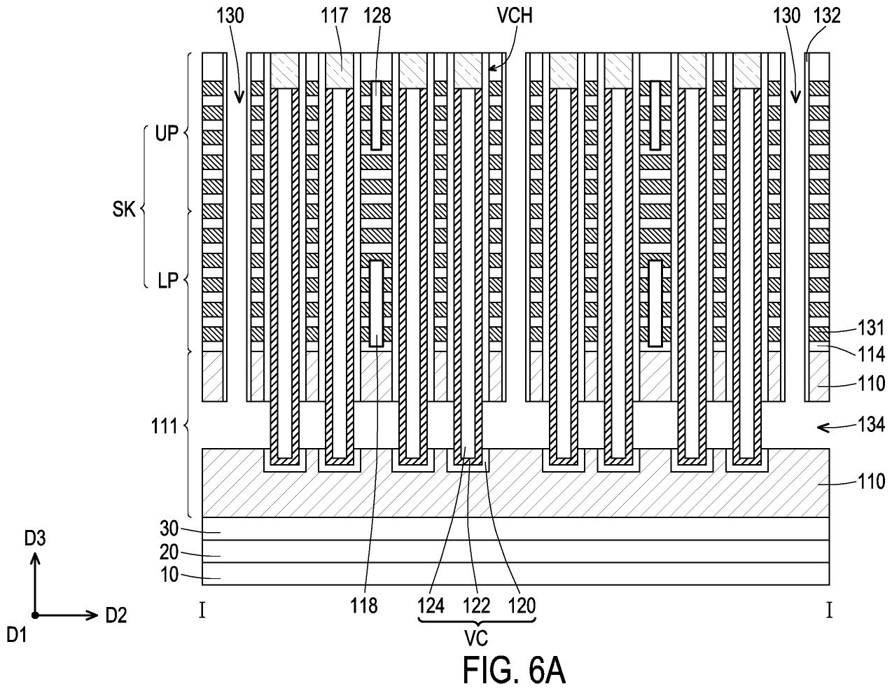

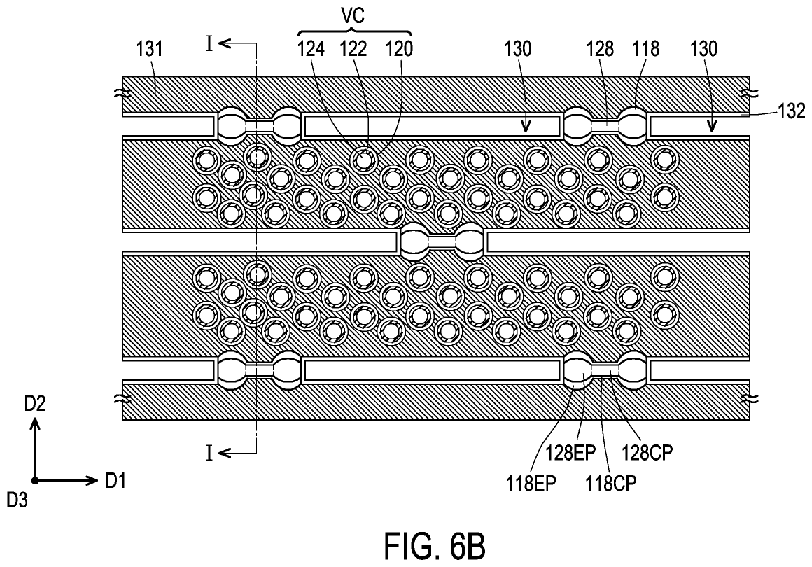

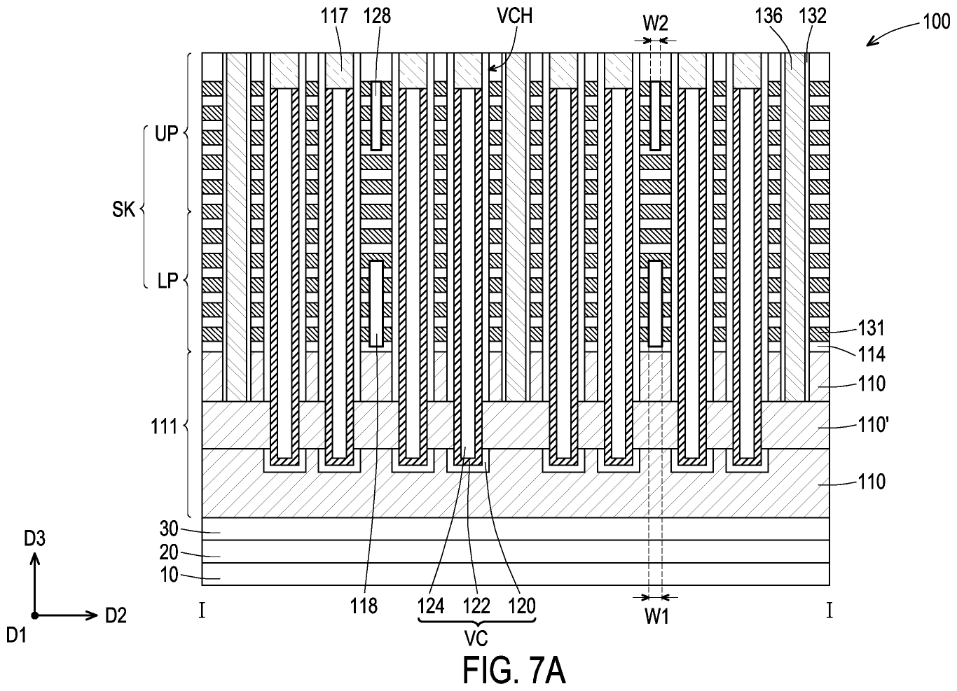

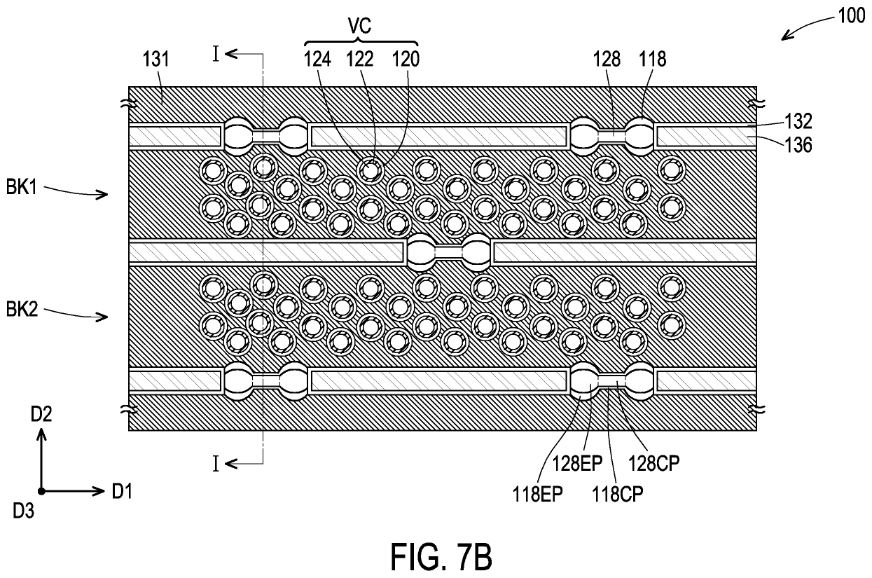

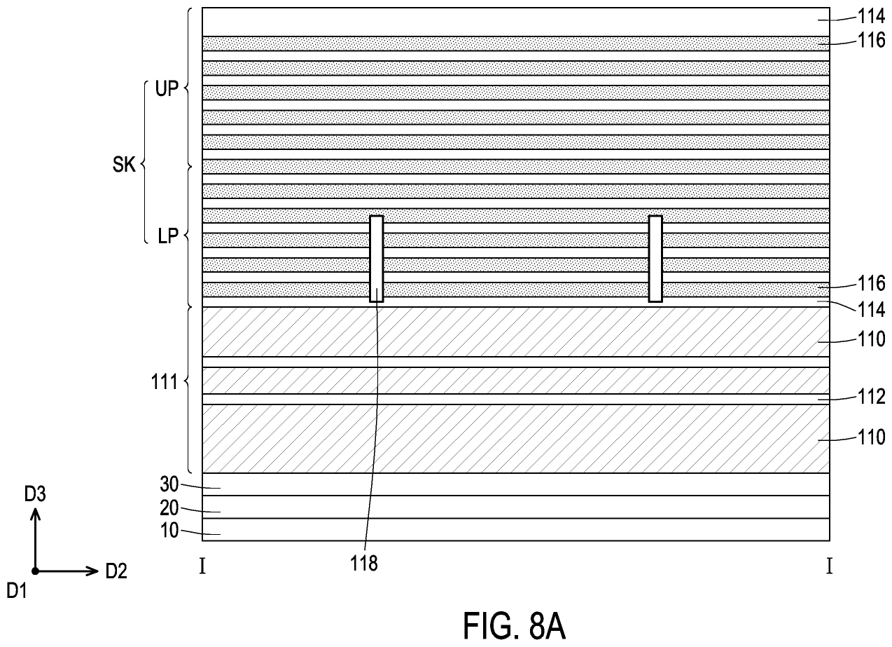

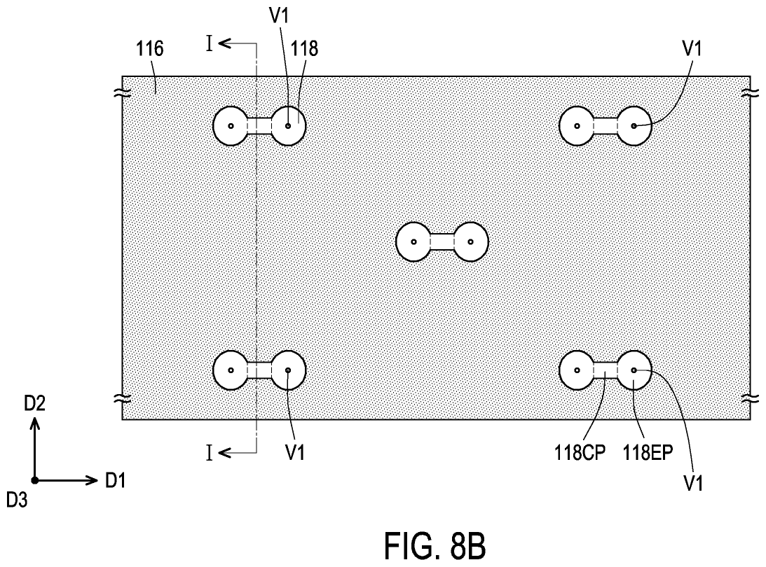

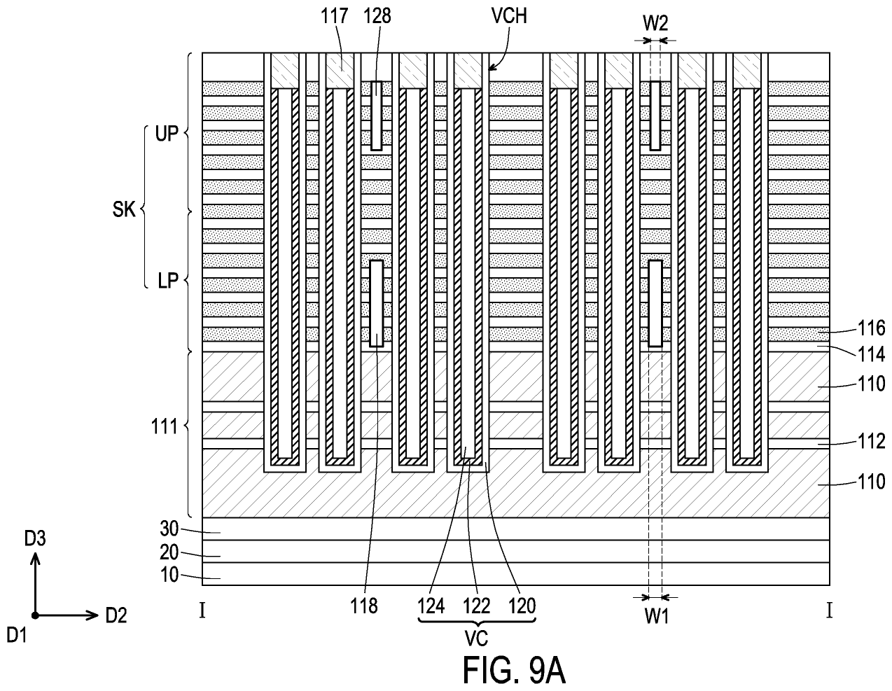

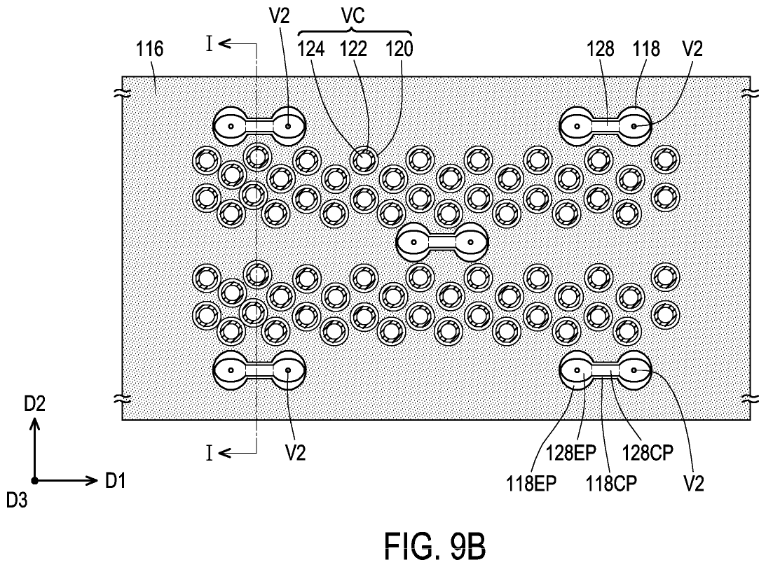

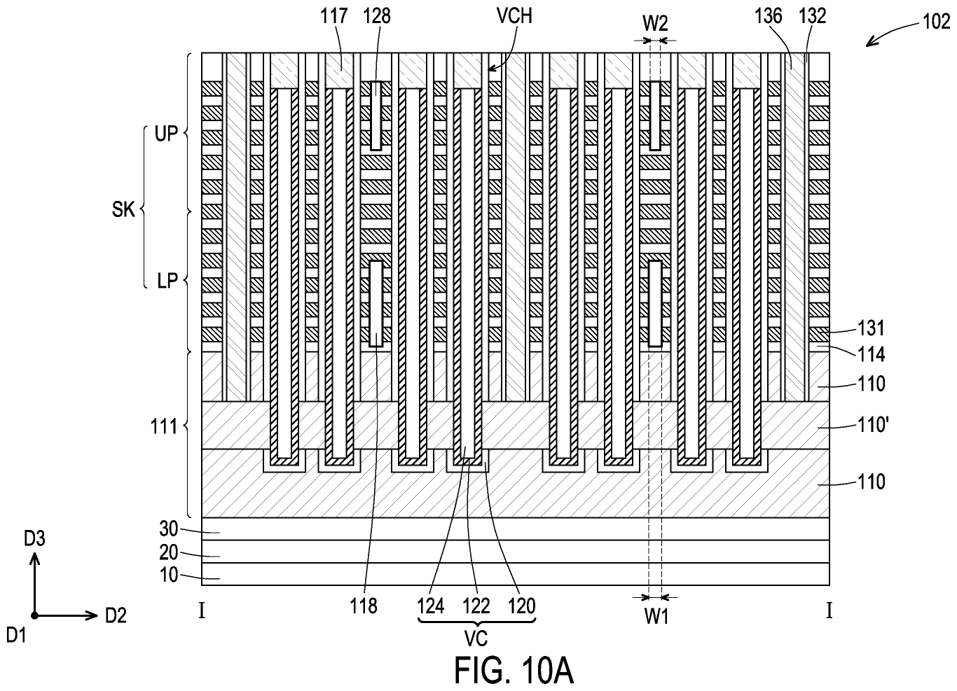

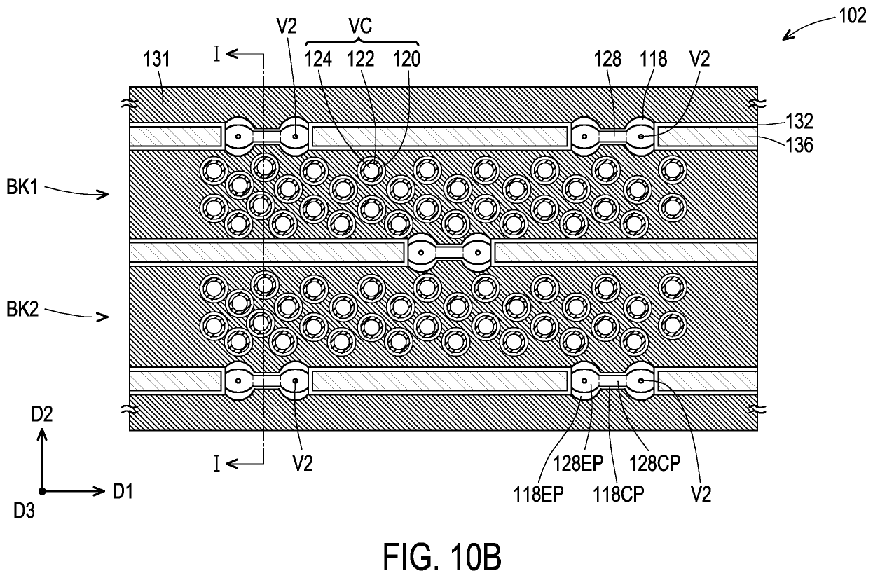

FIG. 8A, FIG. 9A and FIG. 10A are schematic cross-sectional views of a method of forming a memory device according to another embodiment of the present disclosure. FIG. 8B, FIG. 9B and FIG. 10B are simplified top views of a method of forming a memory device according to another embodiment of the present disclosure, in which only few elements are shown for clarity and easy illustration, and these elements are not in the same level. In an embodiment, FIG. 8A, FIG. 9A, and FIG. 10A are cross-sectional views taken along the lines I-I of FIG. 8B, FIG. 9B, and FIG. 10B. The method in FIG. 8A to FIG. 10B is similar to the method in FIG. 1A to FIG. 7B, so the difference between them is described below, and the similarity is not iterated herein.

First, the steps of FIG. 1A and FIG. 1B are performed, so as to form the intermediate structure of FIG. 8A and FIG. 8B. From the top view of FIG. 8B, the first isolation structures 118 have enclosed voids V1 in the wide end portions 118EP thereof.

Next, the steps of FIG. 2A to FIG. 3B are performed, so as to form the intermediate structure of FIG. 9A and FIG. 9B. From the top view of FIG. 9B, the second isolation structures 128 have enclosed voids V2 in the wide end portions 128EP thereof.

Thereafter, the steps in FIG. 4A to FIG. 7B are performed, so as to form the memory device 102 in FIG. 10A and FIG. 10B.

The structures of the memory devices of the present disclosure are described below with reference to FIG. 7A, FIG. 7B, FIG. 10A, and FIG. 10B. In an embodiment, the memory device 100/102 includes, from bottom to top, a substrate 10, a laminated layer 111 and a stacked structure SK. Multiple vertical channel pillars VC penetrate through the stacked structure SK and the laminated layer 111. Multiple first isolation structures 118 are disposed aside the vertical channel pillars VC and penetrate through a lower part LP of the stacked structure SK. Multiple second isolation structures 128 are disposed over the first isolation structures 118 and penetrate through an upper part UP of the stacked structure SK. Multiple common source lines 136 are disposed aside the vertical channel pillars VC and penetrate through the stacked structure SK and a part of the laminated layer 111. From a top view, the common source lines 136 extend in a first direction D1. Each of the first isolation structures 118 and the second isolation structures 128 has, in the first direction D1, two wide end portions 118EP/128EP respectively adjacent to two common source lines 136.

In an embodiment, from the top view, the second isolation structures 128 are respectively overlapped with the first isolation structures 118, and the second isolation structures 128 are respectively located within boundaries of the first isolation structures 118.

In an embodiment, from the top view, each of the first isolation structures 118 and the second isolation structures 128 further has, in the first direction D1, a narrow center portion 118CP/128CP between the two wide end portions 118EP/128EP, and wherein a size of the wide end portions 118EP/128EP in a second direction D2 is greater than a size of the narrow center portion 118CP/128CP in the second direction D2, and the second direction D2 is perpendicular to the first direction D1.

In an embodiment, the size of the wide end portions 118EP of the first isolation structures 118 in the second direction D2 is greater than the size of the wide end portions 128EP of the second isolation structures 128 in the second direction D2.

In an embodiment, the size of the narrow center portions 118CP of the first isolation structures 118 in the second direction D2 is greater than the size of the narrow center portions 128CP of the second isolation structures 128 in the second direction D2.

In an embodiment, from the top view, each of the narrow center portions 118CP/128CP has a substantially fixed width and each of the wide end portions 118EP/128EP has a varied width.

In an embodiment, the stacked structure SK includes multiple insulating layers 114 and multiple conductive layers 131 stacked alternately. In an embodiment, in a third direction D3, the first isolation structures 118 are respectively aligned with the second isolation structures 128 and separated from the second isolation structures 128 by at least one conductive layer 131, and the third direction D3 is perpendicular to the first direction D1.

In an embodiment, the wide end portions 118EP/128EP of the first isolation structures 118 and the second isolation structures 128 have enclosed voids V1/V2 therein.

To sum up, in the present disclosure, a source line isolation structure is formed with wide end portions at two sides thereof, so as to prevent a seam from forming in the source line isolation structure due to over-etching during the formation of the vertical trenches, and therefore prevent a tungsten layer from filling in the seam in the subsequent replacement process to cause the conventional short issue between the adjacent common source lines. Therefore, the reliability of the memory device formed by the present disclosure can be greatly improved.

Although the present disclosure has been disclosed above through embodiments, they are not intended to limit the present disclosure. Anyone with ordinary knowledge in the relevant technical field can make some changes and modifications without departing from the spirit and scope of the present disclosure. Therefore, the protection scope of the present disclosure shall be determined by the appended patent application scope.

What is claimed is:

1. A memory device, comprising:
a laminated layer, disposed on a substrate;
a stacked structure, disposed on the laminated layer;
a plurality of vertical channel pillars, penetrating through the stacked structure and the laminated layer;
a plurality of first isolation structures, disposed aside the plurality of vertical channel pillars and penetrating through a lower part of the stacked structure;
a plurality of second isolation structures, respectively disposed over the plurality of first isolation structures and penetrating through an upper part of the stacked structure; and
a plurality of common source lines, disposed aside the plurality of vertical channel pillars and penetrating through the stacked structure and a part of the laminated layer,
wherein from a top view, the plurality of common source lines extend in a first direction, and each of the first isolation structures and the second isolation structures has, in the first direction, two wide end portions respectively adjacent to two of the common source lines.

2. The memory device of claim 1, wherein from the top view, the second isolation structures are respectively overlapped with the first isolation structures, and the second isolation structures are respectively located within boundaries of the first isolation structures.

3. The memory device of claim 1, wherein from the top view, each of the first isolation structures and the second isolation structures further has, in the first direction, a narrow center portion between the two wide end portions, and wherein a size of the wide end portions in a second direction is greater than a size of the narrow center portion in the second direction, and the second direction is perpendicular to the first direction.

4. The memory device of claim 3, wherein the size of the wide end portions of the first isolation structures in the second direction is greater than the size of the wide end portions of the second isolation structures in the second direction.

5. The memory device of claim 3, wherein the size of the narrow center portions of the first isolation structures in the second direction is greater than the size of the narrow center portions of the second isolation structures in the second direction.

6. The memory device of claim 3, wherein from the top view, each of the narrow center portions has a substantially fixed width, and each of the wide end portions has a varied width.

7. The memory device of claim 1, wherein the stacked structure comprises a plurality of insulating layers and a plurality of conductive layers stacked alternately.

8. The memory device of claim 7, wherein in a third direction, the first isolation structures are respectively aligned with the second isolation structures and separated from the second isolation structures by at least one conductive layer, and the third direction is perpendicular to the first direction.

9. The memory device of claim 1, wherein the wide end portions of the first isolation structures and the second isolation structures have enclosed voids therein.

10. A method of forming a memory device, comprising:
forming a laminated layer on a substrate;
forming a stacked structure on the laminated layer, and the stacked structure comprises a plurality of insulating layers and a plurality of conductive layers stacked alternately; and
forming a plurality of vertical channel pillars, a plurality of first isolation structures and a plurality of second isolation structures in the stacked structure, wherein the vertical channel pillars penetrate through the stacked structure and the laminated layer, the first isolation structures penetrate through a lower part of the stacked structure, and the second isolation structures are respectively disposed over the first isolation structures and penetrate through an upper part of the stacked structure,
wherein from a top view, each of the first isolation structures and the second isolation structures has two wide end portions in a first direction.

11. The method of claim 10, further comprising forming a plurality of vertical trenches, wherein the vertical trenches penetrate through the stacked structure and a part of the laminated layer and extend in the first direction, each of the first isolation structures and the second isolation structures is disposed adjacent to two of the vertical trenches.

12. The method of claim 11, wherein the step of forming the vertical trenches further comprises partially removing the wide end portions of the first isolation structures and the wide end portions of the second isolation structures.

13. The method of claim 11, further comprising: forming an etch stop layer on a sidewall of each of the vertical trenches.

14. The method of claim 13, further comprising, after forming the etch stop layer, removing a middle part of the laminated layer and a portion of the charge storage structure of each of the vertical channel pillars to form a lateral trench.

15. The method of claim 14, further comprising: back-filling a polysilicon layer in the lateral trench.

16. The method of claim 11, further comprising: forming a plurality of common source lines in the plurality of vertical trenches, the common source lines extending in the first direction.

17. The method of claim 10, wherein from the top view, the second isolation structures are respectively overlapped with the first isolation structures, and the second isolation structures are respectively located within boundaries of the first isolation structures.

18. The method of claim 10, wherein from the top view, each of the first isolation structures and the second isolation structures further has, in the first direction, a narrow center portion between the two wide end portions, and wherein a size of the wide end portions in a second direction is greater than a size of the narrow center portion in the second direction, and the second direction is perpendicular to the first direction.

19. The method of claim 10, wherein in a third direction, the first isolation structures are respectively aligned with the second isolation structures and separated from the second isolation structures by at least one conductive layer, and the third direction is perpendicular to the first direction.

20. The method of claim 10, wherein the wide end portions of the first isolation structures and the second isolation structures have enclosed voids therein.
